(19) United States
(12) Patent Application Publication
(10) Pub. No.: US 2025/0308858 A1
(43) Pub. Date: Oct. 2, 2025

(54) PLASMA PROCESSING APPARATUS

(71) Applicant: Tokyo Electron Limited, Tokyo (JP)

(72) Inventors: Takashi TAIRA, Kurokawa-gun (JP); Kazuki HOSHI, Kurokawa-gun (JP)

(73) Assignee: Tokyo Electron Limited, Tokyo (JP)

(21) Appl. No.: 19/240,089

(22) Filed: Jun. 17, 2025

Related U.S. Application Data
(63) Continuation of application No. PCT/JP2023/043366, filed on Dec. 4, 2023.

(30) Foreign Application Priority Data
Dec. 26, 2022 (JP) 2022-208066
Aug. 22, 2023 (JP) 2023-134610

(51) Int. Cl. H01J 37/32

(52) U.S. Cl. CPC H01J 37/32559; H01J 37/32091; H01J 2201/2896

(57) ABSTRACT

A plasma processing apparatus includes a chamber defining a plasma processing space, a substrate support, an upper electrode above the substrate support and being a part of a ceiling extending above the plasma processing space and closing an opening of the chamber to receive radio-frequency power, a first insulating member being a part of the ceiling and located between the upper electrode and the chamber to electrically isolate the upper electrode from the chamber, and a shield being another part of the ceiling, being conductive, and being formed from a silicon-containing material. The shield extends from a peripheral edge of the upper electrode to the chamber. The ceiling includes a portion exposed to the plasma processing space. The portion includes a conductor including the upper electrode and the shield.

### CROSS-REFERENCE TO RELATED APPLICATIONS

This application is a Continuation of PCT International Application No. PCT/JP2023/043366, filed on Dec. 4, 2023, which claims priority under 35 U.S.C. § 119(a) to Japanese Patent Application No. 2022-208066, filed in Japan on Dec. 26, 2022, and Japanese Patent Application No. 2023-134610, filed in Japan on Aug. 22, 2023 all of which are hereby expressly incorporated by reference into the present application.

### FIELD

One or more embodiments of the disclosure relate to a plasma processing apparatus.

### BACKGROUND

A plasma processing apparatus performs plasma processing of substrates. A plasma processing apparatus described in Patent Literature 1 includes a process chamber, an upper electrode, and a shield. The upper electrode closes an opening in the ceiling of the process chamber with the insulating shield between the upper electrode and the ceiling. The upper electrode includes an inner electrode plate inside the process chamber and an outer electrode plate located outward from the inner electrode plate. A space between the inner electrode plate and the outer electrode plate serves as a channel through which a gas flows.

### CITATION LIST

### Patent Literature

Patent Literature 1: Japanese Unexamined Patent Application Publication No. 2021-077808

### BRIEF SUMMARY

### Technical Problem

One or more aspects of the disclosure are directed to a technique for reducing adhesion of a reaction product on a portion exposed to a plasma processing space.

### Solution to Problem

A plasma processing apparatus according to one exemplary embodiment includes a chamber, a substrate support, an upper electrode, a first insulating member, and a shield. The chamber defines a plasma processing space. The substrate support is located in the chamber. The substrate support supports a substrate. The upper electrode is above the substrate support. The upper electrode is a part of a ceiling extending above the plasma processing space and closing an opening of the chamber. The upper electrode receives radio-frequency power. The first insulating member is a part of the ceiling. The first insulating member is located between the upper electrode and the chamber to electrically isolate the upper electrode from the chamber. The shield is another part of the ceiling. The shield is conductive and is formed from a silicon-containing material. The shield extends from a peripheral edge of the upper electrode to the chamber. The ceiling includes a portion exposed to the plasma processing space. The portion includes a conductor including the upper electrode and the shield.

### Advantageous Effects

The technique according to one or more aspects of the disclosure reduces adhesion of a reaction product on the portion exposed to the plasma processing space.

### BRIEF DESCRIPTION OF DRAWINGS

FIG. 1 is a diagram of a plasma processing system, describing an example structure.

FIG. 2 is a diagram of a capacitively coupled plasma processing apparatus, describing an example structure.

FIG. 3 is a diagram of a plasma processing apparatus according to one exemplary embodiment.

FIG. 4 is a graph showing the real part (resistance) of the impedance of a load coupled to a radio-frequency (RF) power supply that varies based on the power levels of RF power provided to the upper electrode.

FIG. 5 is a graph showing the relationship between the plasma density and the real part (resistance) of the impedance of the load coupled to the RF power supply.

FIG. 6 is a diagram of a plasma processing apparatus according to another exemplary embodiment.

FIG. 7 is a block diagram of processing circuitry for performing computer-based operations described herein.

### DETAILED DESCRIPTION

Exemplary embodiments will now be described in detail with reference to the drawings. In the drawings, like reference numerals denote like or corresponding components.

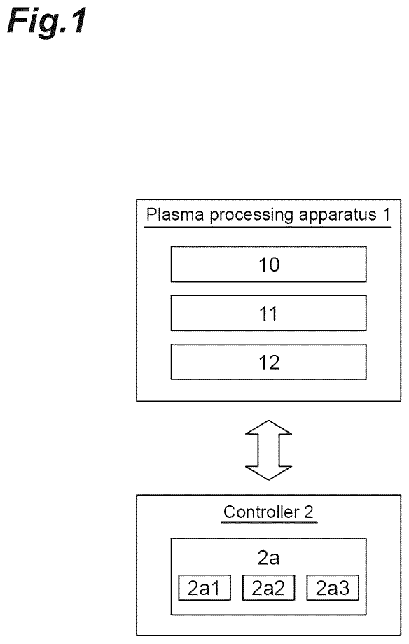

FIG. 1 is a diagram of a plasma processing system, describing an example structure. In one embodiment, the plasma processing system includes a plasma processing apparatus 1 and a controller 2. The plasma processing system is an example of a substrate processing system. The plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 has at least one gas inlet for supplying at least one process gas into the plasma processing space and at least one gas outlet for discharging the gas from the plasma processing space. The gas inlet connects to a gas supply 20 (described later). The gas outlet connects to an exhaust system 40 (described later). The substrate support 11 is located in the plasma processing space and has a substrate support surface for supporting a substrate.

The plasma generator 12 generates plasma from at least one process gas supplied into the plasma processing space. The plasma generated in the plasma processing space may be capacitively coupled plasma (CCP), inductively coupled plasma (ICP), electron cyclotron resonance (ECR) plasma, helicon wave plasma (HWP), or surface wave plasma (SWP). Various plasma generators including an alternating current (AC) plasma generator and a direct current (DC) plasma generator may be used. In one embodiment, an AC signal (AC power) used in the AC plasma generator has a frequency in a range of 100 kHz to 10 GHz. Thus, the AC signal includes a radio-frequency (RF) signal and a microwave signal. In one embodiment, the RF signal has a frequency in a range of 100 kHz to 150 MHz.

The controller 2 processes computer-executable instructions that cause the plasma processing apparatus 1 to perform various steps described in one or more embodiments of the disclosure. The controller 2 may control the components of the plasma processing apparatus 1 to perform various steps described herein. In one embodiment, some or all of the components of the controller 2 may be included in the plasma processing apparatus 1. The controller 2 may include a processor 2a1, a storage 2a2, and a communication interface 2a3. The controller 2 is implemented by, for example, a computer 2a. The processor 2al may perform various control operations by reading a program from the storage 2a2 and executing the read program. This program may be prestored in the storage 2a2 or may be obtained through a medium as appropriate. The obtained program is stored into the storage 2a2, read from the storage 2a2, and executed by the processor 2al. The medium may be one of various storage media readable by the computer 2a, or a communication line connected to the communication interface 2a3. The processor 2al may be a central processing unit (CPU). The storage 2a2 may include a random-access memory (RAM), a read-only memory (ROM), a hard disk drive (HDD), a solid-state drive (SSD), or a combination of these. The communication interface 2a3 may communicate with the plasma processing apparatus 1 through a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

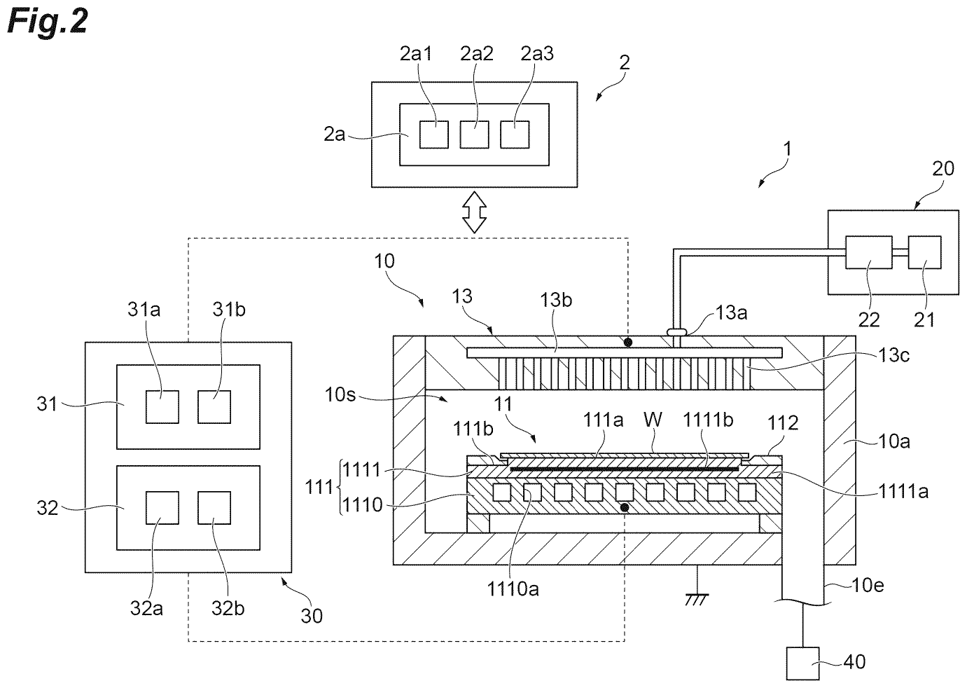

An example structure of a capacitively coupled plasma processing apparatus as an example of the plasma processing apparatus 1 will now be described. FIG. 2 is a diagram of the capacitively coupled plasma processing apparatus, describing an example structure.

The capacitively coupled plasma processing apparatus 1 includes the plasma processing chamber 10, the gas supply 20, a power supply 30, and the exhaust system 40. The plasma processing apparatus 1 also includes the substrate support 11 and a gas guide unit. The gas guide unit allows at least one process gas to be introduced into the plasma processing chamber 10. The gas guide unit includes a shower head 13. The substrate support 11 is located in the plasma processing chamber 10. The shower head 13 is located above the substrate support 11. In one embodiment, the shower head 13 defines at least a part of the ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a body 111 and a ring assembly 112. The body 111 includes a central area 111a for supporting a substrate W and an annular area 111b for supporting the ring assembly 112. A wafer is an example of the substrate W. The annular area 111b of the body 111 surrounds the central area 111a of the body 111 as viewed in plan. The substrate W is located on the central area 111a of the body 111. The ring assembly 112 is located on the annular area 111b of the body 111 to surround the substrate W on the central area 111a of the body 111. Thus, the central area 111a is also referred to as a substrate support surface for supporting the substrate W, and the annular area 111b is also referred to as a ring support surface for supporting the ring assembly 112.

In one embodiment, the body 111 includes a base 1110 and an electrostatic chuck (ESC) 1111. The base 1110 includes a conductive member. The conductive member in the base 1110 may serve as a lower electrode. The ESC 1111 is located on the base 1110. The ESC 1111 includes a ceramic member 1111a and an electrostatic electrode 1111b located inside the ceramic member 1111a. The ceramic member 1111a includes the central area 111a. In one embodiment, the ceramic member 1111a also includes the annular area 111b. The annular area 111b may be included in another member surrounding the ESC 1111, such as an annular ESC or an annular insulating member. In this case, the ring assembly 112 may be located on either the annular ESC or the annular insulating member, or may be located on both the ESC 1111 and the annular insulating member. At least one RF/DC electrode coupled to an RF power supply 31, to a DC power supply 32, or to both (described later) may be located inside the ceramic member 1111a. In this case, at least one RF/DC electrode serves as a lower electrode. When a bias RF signal, a DC signal, or both (described later) are provided to at least one RF/DC electrode, the RF/DC electrode is also referred to as a bias electrode. The conductive member in the base 1110 and at least one RF/DC electrode may serve as multiple lower electrodes. The electrostatic electrode 1111b may also serve as a lower electrode. Thus, the substrate support 11 includes at least one lower electrode.

The ring assembly 112 includes one or more annular members. In one embodiment, one or more annular members include one or more edge rings and at least one cover ring. The edge rings are formed from a conductive material or an insulating material. The cover ring is formed from an insulating material.

The substrate support 11 may also include a temperature control module that adjusts the temperature of at least one of the ESC 1111, the ring assembly 112, or the substrate to a target temperature. The temperature control module may include a heater, a heat transfer medium, a channel 1110a, or a combination of these. The channel 1110a allows a heat transfer fluid such as brine or gas to flow. In one embodiment, the channel 1110a is defined in the base 1110, and one or more heaters are located in the ceramic member 1111a in the ESC 1111. The substrate support 11 may include a heat transfer gas supply to supply a heat transfer gas to a space between the back surface of the substrate W and the central area 111a.

The shower head 13 introduces at least one process gas from the gas supply 20 into the plasma processing space 10s. The shower head 13 has at least one gas inlet 13a, at least one gas-diffusion compartment 13b, and multiple gas guides 13c. The process gas supplied to the gas inlet 13a passes through the gas-diffusion compartment 13b and is introduced into the plasma processing space 10s through the multiple gas guides 13c. The shower head 13 also includes at least one upper electrode. In addition to the shower head 13, the gas guide unit may include one or more side gas injectors (SGIs) installed in one or more openings in the side wall 10a.

The gas supply 20 may include at least one gas source 21 and at least one flow controller 22. In one embodiment, the gas supply 20 supplies at least one process gas from each gas source 21 to the shower head 13 through the corresponding flow controller 22. Each flow controller 22 may include, for example, a mass flow controller or a pressure-based flow controller. The gas supply 20 may further include at least one flow rate modulator that allows supply of at least one process gas at a modulated flow rate or in a pulsed manner.

The power supply 30 includes the RF power supply 31 coupled to the plasma processing chamber 10 through at least one impedance matching circuit. The RF power supply 31 provides at least one RF signal (RF power) to at least one lower electrode, to at least one upper electrode, or to both the electrodes. This causes plasma to be generated from at least one process gas supplied into the plasma processing space 10s. The RF power supply 31 may thus at least partially serve as the plasma generator 12. A bias RF signal is provided to at least one lower electrode to generate a bias potential in the substrate W, thus drawing ion components in the generated plasma to the substrate W.

In one embodiment, the RF power supply 31 includes a first RF generator 31a and a second RF generator 31b. The first RF generator 31a is coupled to at least one lower electrode, to at least one upper electrode, or to both the electrodes through at least one impedance matching circuit and generates a source RF signal (source RF power) for plasma generation. In one embodiment, the source RF signal has a frequency in a range of 10 to 150 MHz. In one embodiment, the first RF generator 31a may generate multiple source RF signals with different frequencies. The generated one or more source RF signals are provided to at least one lower electrode, to at least one upper electrode, or to both the electrodes.

The second RF generator 31b is coupled to at least one lower electrode through at least one impedance matching circuit and generates a bias RF signal (bias RF power). The frequency of the bias RF signal may be the same as or different from the frequency of the source RF signal. In one embodiment, the bias RF signal has a lower frequency than the source RF signal. In one embodiment, the bias RF signal has a frequency in a range of 100 kHz to 60 MHz. In one embodiment, the second RF generator 31b may generate multiple bias RF signals with different frequencies. The generated one or more bias RF signals are provided to at least one lower electrode. In various embodiments, at least one of the source RF signal or the bias RF signal may be pulsed.

The power supply 30 may also include the DC power supply 32 coupled to the plasma processing chamber 10. The DC power supply 32 includes a first DC generator 32a and a second DC generator 32b. In one embodiment, the first DC generator 32a is coupled to at least one lower electrode and generates a first DC signal. The generated first DC signal is applied to at least one lower electrode. In one embodiment, the second DC generator 32b is coupled to at least one upper electrode and generates a second DC signal. The generated second DC signal is applied to at least one upper electrode.

In various embodiments, the first DC signal and the second DC signal may be pulsed. In this case, a sequence of voltage pulses is applied to at least one lower electrode, to at least one upper electrode, or to both the electrodes. The voltage pulses may have a rectangular, trapezoidal, or triangular pulse waveform, or a combination of these pulse waveforms. In one embodiment, a waveform generator for generating a sequence of voltage pulses based on DC signals is coupled between the first DC generator 32a and at least one lower electrode. Thus, the first DC generator 32a and the waveform generator form a voltage pulse generator. When the second DC generator 32b and the waveform generator form a voltage pulse generator, the voltage pulse generator is coupled to at least one upper electrode. The voltage pulses may have positive or negative polarity. The sequence of voltage pulses may also include one or more positive voltage pulses and one or more negative voltage pulses within one cycle. The power supply 30 may include the first DC generator 32a and the second DC generator 32b in addition to the RF power supply 31, or the first DC generator 32a may replace the second RF generator 31b.

The exhaust system 40 is connectable to, for example, a gas outlet 10e in the bottom of the plasma processing chamber 10. The exhaust system 40 may include a pressure control valve and a vacuum pump. The pressure control valve regulates the pressure in the plasma processing space 10s. The vacuum pump may include a turbomolecular pump, a dry pump, or a combination of these.

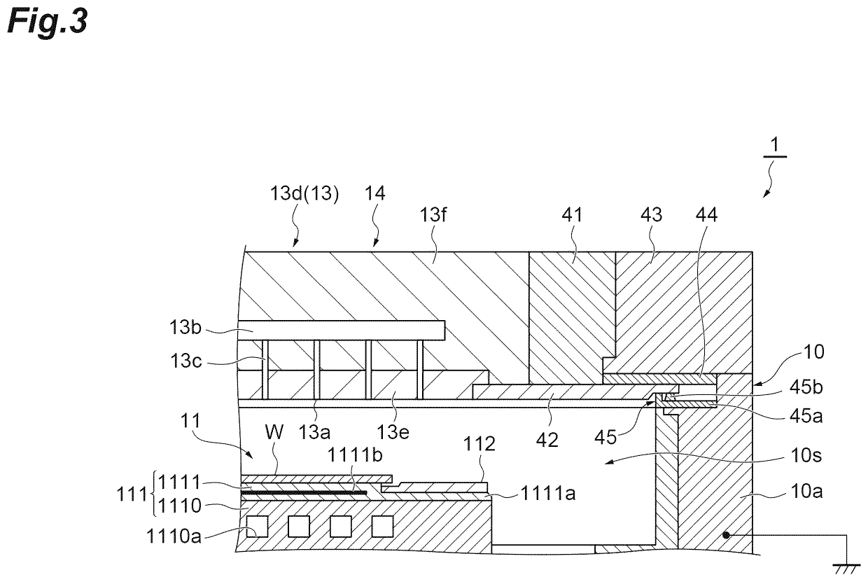

A plasma processing apparatus according to one exemplary embodiment will now be described with reference to FIGS. 2 and 3. FIG. 3 is a diagram of an upper electrode and a shield included in the plasma processing apparatus shown in FIG. 2.

As shown in FIG. 3, the plasma processing chamber 10 has the side wall 10a having a substantially cylindrical shape. The side wall 10a is coupled to the ground, and its potential is set to the ground potential. The side wall 10a has an opening in its upper end.

The plasma processing apparatus 1 includes a ceiling 14 above the plasma processing space 10s. The ceiling 14 closes the opening of the plasma processing chamber 10. More specifically, the ceiling 14 covers and closes the opening in the upper end of the side wall 10a. The ceiling 14 is partially exposed to the plasma processing space 10s.

The shower head 13 defining a part of the ceiling 14 includes at least one upper electrode 13d. The upper electrode 13d is a part of the ceiling 14 and is located above the substrate support 11 to receive RF power. The upper electrode 13d is electrically coupled to, for example, the first RF generator 31a. The first RF generator 31a is an example of an RF power supply.

The upper electrode 13d includes a ceiling plate 13e and a first support 13f. The ceiling plate 13e is substantially disk-shaped. The ceiling plate 13e faces the plasma processing space 10s. The ceiling plate 13e is formed from a conductive material such as silicon, aluminum oxide, or quartz. The ceiling plate 13e may be a conductive member formed from, for example, aluminum with its surface covered with an anticorrosive film. The anticorrosive film is formed from, for example, a material such as aluminum oxide or yttrium oxide.

The first support 13f is located on the ceiling plate 13e. The first support 13f supports the ceiling plate 13e in a detachable manner. The first support 13f is formed from, for example, aluminum. The first support 13f defines at least one gas-diffusion compartment 13b inside. The first support 13f, together with the ceiling plate 13e, defines at least one gas guide 13c. At least one gas guide 13c extends downward from the at least one gas-diffusion compartment 13b through the ceiling plate 13e.

The ceiling 14 further includes a first insulating member 41. The first insulating member 41 is a part of the ceiling 14. The first insulating member 41 is located between the upper electrode 13d and the plasma processing chamber 10. The first insulating member 41 electrically isolates the upper electrode 13d from the plasma processing chamber 10. The first insulating member 41 is located outward (adjacent to the side wall 10a) from the upper electrode 13d. The first insulating member 41 is substantially annular and extends circumferentially to surround the upper electrode 13d. The first insulating member 41 is formed from an insulator such as quartz.

The ceiling 14 further includes a shield 42. The shield 42 is another part of the ceiling 14 and is conductive. The shield 42 is formed from, for example, a silicon-containing material. The shield 42 extends from the peripheral edge of the upper electrode 13d to the plasma processing chamber 10. The shield 42 extends circumferentially to surround a peripheral portion of the ceiling plate 13e. The shield 42 is, for example, substantially annular. The shield 42 is electrically floating. More specifically, the shield 42 has a floating potential different from the potential of the upper electrode 13d and the potential of the plasma processing chamber 10.

A portion of the ceiling 14 exposed to the plasma processing space 10s includes a conductor including the upper electrode 13d and the shield 42. For example, the portion of the ceiling 14 exposed to the plasma processing space 10s includes the conductor alone. The portion of the ceiling 14 exposed to the plasma processing space 10s is hereafter referred to as an exposed portion of the ceiling 14. In the example shown in FIG. 3, the exposed potion of the ceiling 14 includes the upper electrode 13d (or the ceiling plate 13e) and the shield 42 alone. The shield 42 is located, for example, below the first insulating member 41. The shield 42 extends without exposing the first insulating member 41 to the plasma processing space 10s. In the example shown in FIG. 3, the shield 42 is below a part of the first support 13f, the first insulating member 41, and a part of a second support 43 (described later).

In the plasma processing apparatus 1, the exposed portion of the ceiling 14 is entirely formed from a conductive material. This allows removal of a reaction product adhering to the exposed portion using an electrical bias during dry cleaning. The reaction product is thus less likely to adhere to the substrate W as particles.

The plasma processing chamber 10 may further include the second support 43. The second support 43 is located outward from the first insulating member 41 and above the shield 42. A small space is left between the second support 43 and the shield 42. The second support 43 is located on the side wall 10a of the plasma processing chamber 10. The second support 43 is electrically coupled to the side wall 10a of the plasma processing chamber 10. The second support 43 has the ground potential. The first insulating member 41 is located between the first support 13f in the upper electrode 13d and the second support 43. The second support 43 is substantially annular and extends circumferentially to surround the first insulating member 41. The second support 43 is formed from a metal such as aluminum.

The plasma processing apparatus 1 further includes at least one second insulating member 44. The at least one second insulating member 44 is located outward from the first insulating member 41 and on the shield 42. The at least one second insulating member 44 is located between the plasma processing chamber 10 and the shield 42. In the example shown in FIG. 3, the at least one second insulating member 44 has a lower surface in contact with the upper surface of an outer portion of the shield 42. The at least one second insulating member 44 is located between the shield 42 and the second support 43. The at least one second insulating member 44 is, for example, a substantially annular plate member. The at least one second insulating member 44 is formed from an insulator such as an insulating ceramic material, quartz, or a metal oxide.

The plasma processing apparatus 1 further includes at least one third insulating member 45. The at least one third insulating member 45 is located below the shield 42. The at least one third insulating member 45 is located between the plasma processing chamber 10 and the shield 42. The shield 42 is supported between the at least one second insulating member 44 and the at least one third insulating member 45.

In the example shown in FIG. 3, the at least one third insulating member 45 includes a third support 45a and a seal 45b. The third support 45a is located on the side wall 10a. The third support 45a supports the shield 42 from below. An inner portion of the third support 45a may be exposed to the plasma processing space 10s below the ceiling 14. The seal 45b is located between the shield 42 and the third support 45a. The seal 45b is in contact with an outer portion of the shield 42 and an outer portion of the third support 45a. The seal 45b is, for example, an O-ring that separates a reduced pressure environment including the plasma processing space 10s from an atmospheric pressure environment.

A path through which a current based on the RF power provided to the upper electrode 13d flows may be a first path passing through no plasma and a second path passing through plasma. The first path allows the current to flow from the upper electrode 13d to the side wall 10a through the shield 42, the at least one second insulating member 44, and the second support 43. The second path allows the current to flow from the upper electrode 13d to the side wall 10a through the plasma in the plasma processing space 10s. The at least one second insulating member 44 lowers the capacitance between the shield 42 and the second support 43 and increases the impedance of the first path. The RF power provided to the upper electrode 13d is more efficiently coupled to the plasma in the plasma processing space 10s. The RF power provided to the upper electrode 13d is coupled to the plasma more efficiently also below the shield 42.

To determine whether RF power is efficiently coupled to the plasma in the plasma processing space 10s in the second path, variation detectable in the impedance circuit (matcher) included in the power supply 30 can be monitored. When RF power is coupled to plasma more efficiently, the impedance circuit detects a higher resistance as the plasma density increases. The impedance circuit detects a lower resistance as the plasma density decreases. The resistance is the real part of the impedance of a load detected by the impedance circuit.

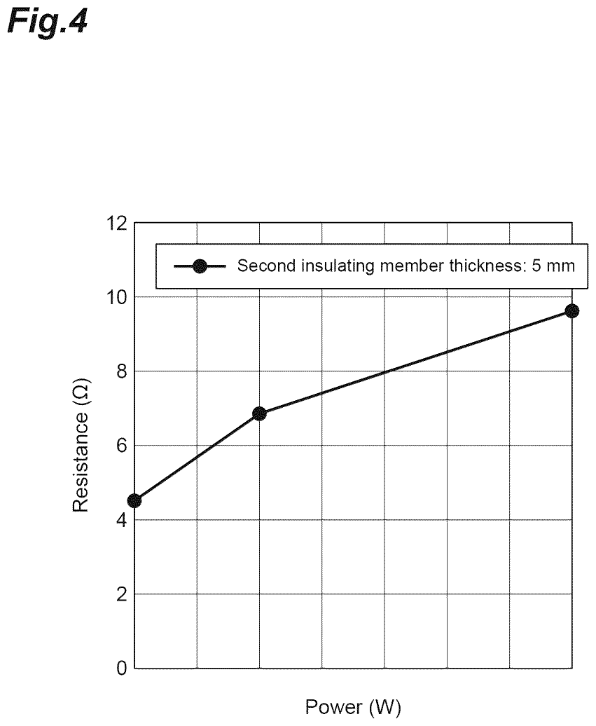

FIG. 4 will now be referred to. FIG. 4 is a graph showing the real part (resistance) of the impedance of a load coupled to the RF power supply that varies based on the power levels of RF power provided to the upper electrode. In the graph shown in FIG. 4, the horizontal axis indicates the power level (W) of RF power provided to the upper electrode 13d, and the vertical axis indicates the real part of the impedance of the load coupled to the RF power supply (first RF generator 31a), or the resistance ((2). The horizontal axis in FIG. 4 indicates that the power level (W) of RF power increases from left to right. The characteristics shown in the graph in FIG. 4 are obtained with a 5-mm-thick second insulating member 44 between the shield 42 and the second support 43. The second insulating member 44 is a quartz member. The space between the upper electrode 13d and the shield 42 measures 0.5 mm. The graph shown in FIG. 4 shows the resistance for varied power levels of RF power. The impedance of the load coupled to the RF power supply (the first RF generator 31a) and its real part (resistance) are detected by the matcher coupled between the RF power supply and the upper electrode 31d.

As shown in FIG. 4, the real part of the impedance of the load coupled to the RF power supply, or the resistance, increases as the power level of RF power increases. The resistance varies linearly as the power level of RF power increases. This indicates that the RF power is efficiently coupled to the plasma.

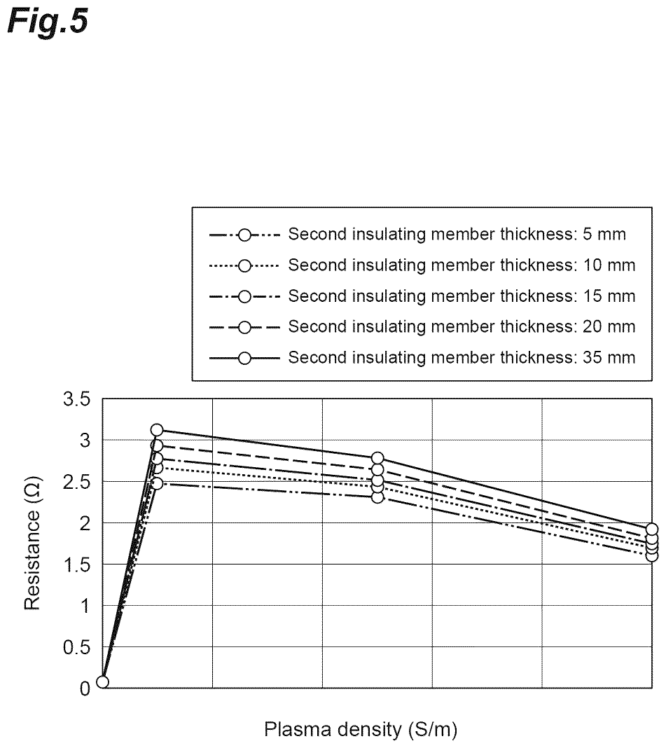

FIG. 5 is a graph showing the relationship between the plasma density and the real part (resistance) of the impedance of the load coupled to the RF power supply. In the graph shown in FIG. 5, the horizontal axis indicates the plasma density (S/m), and the vertical axis indicates the real part of the impedance of the load coupled to the RF power supply (the first RF generator 31a), or the resistance ((2). The horizontal axis in FIG. 5 indicates that the plasma density (S/m) increases from left to right. FIG. 5 shows the measurement results for the second insulating members 44 each having a thickness of 5, 10, 15, 20, or 35 mm.

As shown in FIG. 5, when plasma is being generated, the real part of the impedance of the load coupled to the RF power supply, or the resistance, decreases as the plasma density increases. This result indicates that the plasma density can be determined based on the resistance and that the plasma density can be controlled based of the resistance. As shown in FIG. 5, thicker second insulating members 44 cause greater variations in the resistance when the plasma density varies. This indicates that, with a thicker second insulating member 44, the variation in the plasma density can be easily detected and the plasma density can be easily controlled.

Although the exemplary embodiments have been described above, the embodiments are not restrictive, and various additions, omissions, substitutions, and changes may be made. The components in the different exemplary embodiments may be combined to form another exemplary embodiment. For example, at least one of the upper electrode 13d or the shield 42 may be electrically coupled to the second DC generator 32b. The second DC generator 32b is an example of a DC power supply.

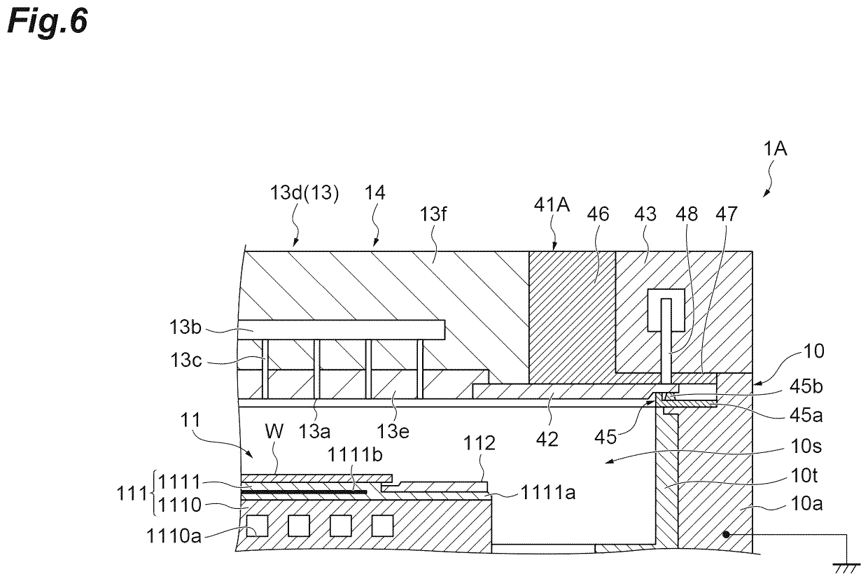

A plasma processing apparatus according to another exemplary embodiment used in the plasma processing apparatus will now be described with reference to FIG. 6. FIG. 6 is a diagram of a plasma processing apparatus according to another exemplary embodiment. A plasma processing apparatus 1A according to the exemplary embodiment shown in FIG. 6 differs from the plasma processing apparatus 1 in that a first insulating member 41A includes a first insulating portion 46 and a second insulating portion 47. More specifically, the plasma processing apparatus 1A differs from the plasma processing apparatus 1 in that the plasma processing apparatus 1A includes no second insulating member 44 included in the plasma processing apparatus 1.

The ceiling 14 includes the first insulating member 41A. The first insulating member 41A is a part of the ceiling 14. The first insulating member 41A is formed from an insulator such as quartz. The first insulating member 41A includes the first insulating portion 46. The first insulating portion 46 is located between the upper electrode 13d and the plasma processing chamber 10. The first insulating portion 46 electrically isolates the upper electrode 13d from the plasma processing chamber 10. The first insulating portion 46 is located outward (adjacent to the side wall 10a) from the upper electrode 13d. The first insulating portion 46 is substantially annular and extends circumferentially to surround the upper electrode 13d.

The second insulating portion 47 is located outward from the first insulating portion 46 and on the shield 42. The second insulating portion 47 is, for example, substantially annular and extends circumferentially to surround the first insulating portion 46. The second insulating portion 47 extends to protrude outward from the lower end of the first insulating portion 46. The second insulating portion 47 is located between the plasma processing chamber 10 and the shield 42. In the example shown in FIG. 6, the second insulating portion 47 has a lower surface in contact with the upper surface of an outer portion of the shield 42. The second insulating portion 47 is located between the shield 42 and the second support 43.

Thus, in the plasma processing apparatus 1A, the first insulating member 41A including the first insulating portion 46 and the second insulating portion 47 is located between the upper electrode 13d and the plasma processing chamber 10 as well as between the plasma processing chamber 10 and the shield 42. This structure uses fewer members to insulate currents and can reduce the work-hours to install the plasma processing apparatus 1A.

The second support 43 includes a DC connector 48 inside. The DC connector 48 extends from the inside of the second support 43 and connects to an outer portion of the shield 42 through the second insulating portion 47. The outer portion of the shield 42 is, for example, a radially outer portion of the shield 42 that is not exposed to the plasma processing space 10s. The outer portion of the shield 42 may be a peripheral portion of the shield 42. The outer portion of the shield 42 is supported between the lower end of the DC connector 48 and the at least one third insulating member 45. For example, the lower end of the DC connector 48 is located immediately above the seal 45b in the at least one third insulating member 45 in the circumferential direction. The shield 42 in the plasma processing apparatus 1A may not be electrically floating.

A second DC signal generated by the second DC generator 32b is applied to the shield 42 through the DC connector 48. The second DC generator 32b generates, as the second DC signal, a signal having a frequency of, for example, 400 kHz and provides the signal to the shield 42 through the DC connector 48. For example, the first RF generator 31a may generate a signal having a frequency of, for example, 100 MHz as a source RF signal and provide the signal to the upper electrode 13d. Additionally, the second RF generator 31b may generate a signal having a frequency of, for example, 13 MHz as a bias RF generation signal and provide the signal to the lower electrode. In this manner, although the DC connector 48 is located outward from the first insulating member 41A, the DC connector 48 connecting to the shield 42 through the second insulating portion 47 can apply the second DC signal appropriately to the shield 42.

An inner wall 10t inward from the side wall 10a and facing the plasma processing space 10s is formed from silicon. The inner wall 10t may serve as an opposing electrode for the shield 42. At least a part of the current applied to the shield 42 flows to the side wall 10a through the plasma in the plasma processing space 10s and the inner wall 10t. The inner wall 10t formed from silicon thus eliminates any separate member (device) serving as an opposing electrode to be located in the plasma processing space 10s. This can reduce the work-hours to install the plasma processing apparatus 1A.

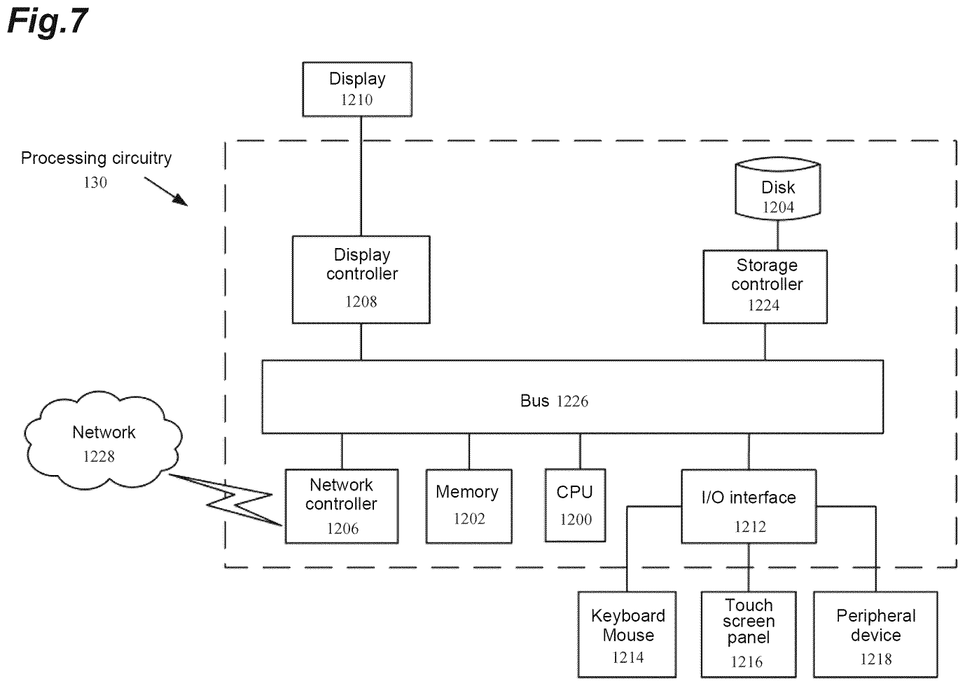

Example processing circuitry that may be used as one or more processing circuits will now be described. Examples of the processing circuitry include the controller 2 in the plasma processing apparatus 1. FIG. 7 is a block diagram of processing circuitry for performing computer-based operations described herein. FIG. 7 illustrates processing circuitry 130 that may be used to control any computer-based control processes. The descriptions or blocks in any flowchart represent modules, segments, or portions of a code including one or more executable instructions for implementing specific logical functions or steps in the processes. Alternate implementations are included within the scope of the exemplary embodiments of the disclosure in which functions can be executed in an order different from the order shown or discussed, including substantially concurrently or in reverse order, depending on the functionality involved as will be understood by those skilled in the art. The various elements, features, and processes described herein may be used independently of one another or may be combined in various ways. All possible combinations and sub-combinations are intended to fall within the scope of the disclosure.

In FIG. 7, the processing circuitry 130 includes a CPU 1200 that performs one or more of control processes described above or described below. The processing data and instructions may be stored in a memory 1202. These processing data and instructions may be stored in a storage medium disk 1204, such as an HDD or a portable storage medium, or may be stored remotely. Further, the techniques described in the scope of the claims are not limited to the form of the computer-readable media in which instructions for the inventive processes are stored. For example, the instructions may be stored in any other information processing device such as a compact disc (CD), a digital versatile disc (DVD), a flash memory, a RAM, a ROM, a programmable ROM (PROM), an erasable programmable ROM (EPROM), an electrically erasable programmable (EEPROM), a hard disk drive, or at least one of a server or a computer with which the processing circuitry 130 communicates.

The techniques described in the scope of the claims may be provided as a utility application, a background daemon, a component of an operating system, or a combination of these, or may be implemented in cooperation with the CPU 1200 and an operating system such as Microsoft Windows, UNIX, Solaris, LINUX, Apple MAC-OS, and other systems known to those skilled in the art.

The hardware elements to achieve the processing circuitry 130 can be implemented by various circuit elements. Further, each of the functions of the above embodiments may be implemented by circuitry, which includes one or more processing circuits. As shown in FIG. 7, the processing circuitry includes a specifically programmed processor, for example, the processor (or CPU) 1200. The processing circuitry also includes devices such as an application-specific integrated circuit (ASIC) or known circuit components to perform the described functions.

In FIG. 7, the processing circuitry 130 includes the CPU 1200 that performs the processes described above. The processing circuitry 130 may be a general-purpose computer or a specific dedicated machine. In one embodiment, the processing circuitry 130 functions as a specific dedicated machine when the processor 1200 is programmed to control the plasma generator 12 and the gas supply 20 (in particular, to perform any of the processes described with reference to FIGS. 1 to 6).

Alternatively, or additionally, the CPU 1200 may be implemented on a field-programmable gate array (FPGA), an ASIC, or a programmable logic device (PLD), or using a discrete logic circuit, as will be understood by those skilled in the art. Further, the CPU 1200 may be implemented as multiple processors cooperatively working in parallel to perform the instructions of the processes in the embodiments of the present invention described above.

The processing circuitry 130 in FIG. 7 also includes a network controller 1206, such as an Intel Ethernet PRO network interface card from Intel Corporation of America, for connecting to a network 1228. As can be understood, the network 1228 may be a public network such as the Internet, a private network such as a LAN or wide area network (WAN), or any combination of these, or may also include a sub-network such as a public switched telephone network (PSTN) or an integrated services digital network (ISDN). The network 1228 may also be a wired network, such as an Ethernet network, or may be a wireless network, such as a cellular network including Enhanced Data GSM Environment (EDGE), 3G, and 4G wireless cellular systems. The wireless network may also be Wi-Fi, Bluetooth, or in any other known wireless communication form.

The processing circuitry 130 further includes a display controller 1208, such as a graphics card or graphics adaptor for interfacing with a display 1210, such as a monitor. A general-purpose input-output (I/O) interface 1212 interfaces with at least one of a keyboard or a mouse 1214 as well as with a touchscreen 1216 integral with or separate from the display 1210. The general-purpose I/O interface is also connected to various peripheral devices 1218, such as a printer and a scanner.

A storage controller 1224 is connected to the storage medium disk 1204 with a communication bus 1226, which may be an Industry Standard Architecture (ISA), Extended Industry Standard Architecture (EISA), Video Electronics Standards Association (VESA) Local Bus, or Peripheral Component Interconnect (PCI) for interconnecting all the components of the processing circuitry 130. The general features and functions of the display 1210, at least one of the keyboard or the mouse 1214, the display controller 1208, the storage controller 1224, a network controller 1206, a sound controller 1220, and a general-purpose I/O interface 1212 will not be described herein for simplicity.

The exemplary circuit elements described in the context of the disclosure may be replaced with other elements and structured differently from the examples provided herein. Further, circuitry that performs the features described herein may be implemented by multiple circuit units (e.g., chips) or may incorporate these features into circuitry of a single chipset.

The functions and features described herein may also be implemented by various distributed components of the system. For example, one or more processors may perform the functions of the system. In this case, the processors may be distributed across multiple components communicating in a network. The distributed components may include one or more clients and server machines that can share processing, in addition to various human interfaces and communication devices (e.g., display monitors, smartphones, tablets, and personal digital assistants or PDAs). The network may be a private network, such as a LAN or WAN, or may be a public network, such as the Internet. Input into the system may be received directly by a user, or may be received remotely either in real time or as a batch process. Additionally, some implementations may be performed on modules or hardware not identical to those described. Other implementations are thus within the scope that may be claimed.

Various exemplary embodiments E1 to E20 included in the disclosure are described below.

E1 A plasma processing apparatus, comprising:
a chamber defining a plasma processing space;
a substrate support in the chamber, the substrate support being configured to support a substrate;
an upper electrode located above the substrate support, the upper electrode being a part of a ceiling extending above the plasma processing space and closing an opening of the chamber, the upper electrode being configured to receive radio-frequency power;
a first insulating member being a part of the ceiling, the first insulating member being located between the upper electrode and the chamber to electrically isolate the upper electrode from the chamber; and
a shield being another part of the ceiling, the shield being conductive and comprising a silicon-containing material, the shield extending from a peripheral edge of the upper electrode to the chamber,
wherein the ceiling includes a portion exposed to the plasma processing space, and the portion includes a conductor including the upper electrode and the shield.

E2 The plasma processing apparatus according to E1, further comprising:
at least one second insulating member located outward from the first insulating member, on the shield, and between the chamber and the shield.

E3 The plasma processing apparatus according to E2, further comprising:
at least one third insulating member located below the shield and between the chamber and the shield, the shield being supported between the at least one second insulating member and the at least one third insulating member.

E4 The plasma processing apparatus according to E3, wherein
the at least one third insulating member comprises an insulating ceramic material, quartz, or a metal oxide.

### E5

E5 The plasma processing apparatus according to E1, wherein
the first insulating member includes
   a first insulating portion between the upper electrode and the chamber, and
   a second insulating portion located outward from the first insulating portion, on the shield, and between the chamber and the shield.

E6 The plasma processing apparatus according to E5, further comprising:
at least one other insulating member located below the shield and between the chamber and the shield, the shield being supported between the second insulating portion of the first insulating member and the at least one other insulating member.

E7 The plasma processing apparatus according to E6, wherein
the at least one other insulating member comprises an insulating ceramic material, quartz, or a metal oxide.

E8 The plasma processing apparatus according to any one of E1 to E7, further comprising:
a direct current power supply electrically coupled to at least one of the upper electrode or the shield.

E9 The plasma processing apparatus according to any one of E1 to E7, wherein
the shield is electrically floating.

### E10

E10 The plasma processing apparatus according to any one of E1 to E9, further comprising:
a radio-frequency power supply electrically coupled to the upper electrode, the radio-frequency power supply being configured to generate the radio-frequency power.

E11 A plasma processing apparatus, including:
a chamber defining a plasma processing space;
a substrate support in the chamber, the substrate support being configured to support a substrate;
an upper electrode located above the substrate support, the upper electrode being a part of a ceiling extending above the plasma processing space and closing an opening of the chamber, the upper electrode being configured to receive radio-frequency power;
a first insulating member being a part of the ceiling, the first insulating member being located between the upper electrode and the chamber to electrically isolate the upper electrode from the chamber; and
a shield being another part of the ceiling, the shield being conductive and comprising a silicon-containing material, the shield extending from a peripheral edge of the upper electrode to the chamber and the shield extending from a peripheral edge of the first insulating member to the chamber,
wherein the ceiling includes a portion exposed to the plasma processing space, and the portion includes a conductor including the upper electrode and the shield.

E12 The plasma processing apparatus according to E11, wherein the upper electrode includes:
a ceiling plate facing the plasma processing space and being conductive; and
a first support supporting the ceiling plate and defining at least one gas-diffusion compartment.

E13 The plasma processing apparatus according to E12, wherein
the ceiling plate is formed of aluminum and has a surface covered with an anticorrosive film, and
the first support supports the ceiling plate in a detachable manner.

E14 The plasma processing apparatus according to E12 or E13, wherein the chamber includes a sidewall, and
the plasma processing apparatus further comprises a second support disposed on the sidewall and outward from the first insulating member.

E15 The plasma processing apparatus according to any one of E11 to E14, further comprising:
at least one second insulating member located outward from the first insulating member, on the shield, and between the chamber and the shield.

E16 The plasma processing apparatus according to any one of E11 to E15, further comprising:
at least one third insulating member located below the shield and between the chamber and the shield, the shield being supported between the at least one second insulating member and the at least one third insulating member.

E17 The plasma processing apparatus according to E16, wherein
the at least one third insulating member comprises an insulating ceramic material, quartz, or a metal oxide.

E18 The plasma processing apparatus according to any one of E11 to E14, wherein
the first insulating member includes:
   a first insulating portion between the upper electrode and the chamber, and
   a second insulating portion located outward from the first insulating portion, on the shield, and between the chamber and the shield.

E19 The plasma processing apparatus according to E18, further comprising:
at least one other insulating member located below the shield and between the chamber and the shield, the shield being supported between the second insulating portion of the first insulating member and the at least one other insulating member.

E20 A plasma processing apparatus, including:
a chamber defining a plasma processing space;
a substrate support in the chamber, the substrate support being configured to support a substrate;
an upper electrode located above the substrate support, the upper electrode being a part of a ceiling extending above the plasma processing space and closing an opening of the chamber, the upper electrode being configured to receive radio-frequency power;
a first insulating member being a part of the ceiling, the first insulating member being located between the upper electrode and the chamber to electrically isolate the upper electrode from the chamber; and
a shield being another part of the ceiling, the shield being conductive and comprising a silicon-containing material, the shield extending from a peripheral edge of the upper electrode to the chamber and the shield extending from a peripheral edge of the first insulating member to the chamber;
at least one second insulating member located outward from the first insulating member, on the shield, and between the chamber and the shield,
wherein the upper electrode includes:
   a ceiling plate facing the plasma processing space and being conductive; and
   a first support supporting the ceiling plate and defining at least one gas-diffusion compartment, and
   the ceiling includes a portion exposed to the plasma processing space, and the portion includes a conductor including the upper electrode and the shield.

The exemplary embodiments according to the disclosure have been described by way of example, and various changes may be made without departing from the scope and spirit of the disclosure. The exemplary embodiments disclosed above are thus not restrictive, and the true scope and spirit of the disclosure are defined by the appended claims.

### REFERENCE SIGNS LIST

1, 1A Plasma processing apparatus
2 Controller
10 Plasma processing chamber
10a Side wall
10s Plasma processing space
11 Substrate support
12 Plasma generator
13 Shower head
13d Upper electrode
13e Ceiling plate
13f First support
14 Ceiling
30 Power supply
31 RF power supply
31a First RF generator
32 DC power supply
32b Second DC generator
41, 41A First insulating member
42 Shield
43 Second support
44 Second insulating member
45 Third insulating member
46 First insulating portion
47 Second insulating portion
111 Body
112 Ring assembly
1110 Base
1111 Electrostatic chuck (ESC)
W Substrate

1. A plasma processing apparatus, comprising:
a chamber defining a plasma processing space;
a substrate support in the chamber, the substrate support being configured to support a substrate;
an upper electrode located above the substrate support, the upper electrode being a part of a ceiling extending above the plasma processing space and closing an opening of the chamber, the upper electrode being configured to receive radio-frequency power;
a first insulating member being a part of the ceiling, the first insulating member being located between the upper electrode and the chamber to electrically isolate the upper electrode from the chamber; and
a shield being another part of the ceiling, the shield being conductive and comprising a silicon-containing material, the shield extending from a peripheral edge of the upper electrode to the chamber,
wherein the ceiling includes a portion exposed to the plasma processing space, and the portion includes a conductor including the upper electrode and the shield.

2. The plasma processing apparatus according to claim 1, further comprising:
at least one second insulating member located outward from the first insulating member, on the shield, and between the chamber and the shield.

3. The plasma processing apparatus according to claim 2, further comprising:
at least one third insulating member located below the shield and between the chamber and the shield, the shield being supported between the at least one second insulating member and the at least one third insulating member.

4. The plasma processing apparatus according to claim 3, wherein
the at least one third insulating member comprises an insulating ceramic material, quartz, or a metal oxide.

5. The plasma processing apparatus according to claim 1, wherein
the first insulating member includes
a first insulating portion between the upper electrode and the chamber, and
a second insulating portion located outward from the first insulating portion, on the shield, and between the chamber and the shield.

6. The plasma processing apparatus according to claim 5, further comprising:
at least one other insulating member located below the shield and between the chamber and the shield, the shield being supported between the second insulating portion of the first insulating member and the at least one other insulating member.

7. The plasma processing apparatus according to claim 6, wherein
the at least one other insulating member comprises an insulating ceramic material, quartz, or a metal oxide.

8. The plasma processing apparatus according to claim 1, further comprising:
a direct current power supply electrically coupled to at least one of the upper electrode or the shield.

9. The plasma processing apparatus according to claim 1, wherein
the shield is electrically floating.

10. The plasma processing apparatus according to claim 1, further comprising:
a radio-frequency power supply electrically coupled to the upper electrode, the radio-frequency power supply being configured to generate the radio-frequency power.

11. A plasma processing apparatus, including:
a chamber defining a plasma processing space;
a substrate support in the chamber, the substrate support being configured to support a substrate;
an upper electrode located above the substrate support, the upper electrode being a part of a ceiling extending above the plasma processing space and closing an opening of the chamber, the upper electrode being configured to receive radio-frequency power;
a first insulating member being a part of the ceiling, the first insulating member being located between the upper electrode and the chamber to electrically isolate the upper electrode from the chamber; and
a shield being another part of the ceiling, the shield being conductive and comprising a silicon-containing material, the shield extending from a peripheral edge of the upper electrode to the chamber and the shield extending from a peripheral edge of the first insulating member to the chamber,
wherein the ceiling includes a portion exposed to the plasma processing space, and the portion includes a conductor including the upper electrode and the shield.

12. The plasma processing apparatus according to claim 11, wherein the upper electrode includes:
a ceiling plate facing the plasma processing space and being conductive; and
a first support supporting the ceiling plate and defining at least one gas-diffusion compartment.

13. The plasma processing apparatus according to claim 12, wherein
the ceiling plate is formed of aluminum and has a surface covered with an anticorrosive film, and
the first support supports the ceiling plate in a detachable manner.

14. The plasma processing apparatus according to claim 12, wherein the chamber includes a sidewall, and
the plasma processing apparatus further comprises a second support disposed on the sidewall and outward from the first insulating member.

15. The plasma processing apparatus according to claim 14, further comprising:
at least one second insulating member located outward from the first insulating member, on the shield, and between the chamber and the shield.

16. The plasma processing apparatus according to claim 15, further comprising:
at least one third insulating member located below the shield and between the chamber and the shield, the shield being supported between the at least one second insulating member and the at least one third insulating member.

17. The plasma processing apparatus according to claim 16, wherein
the at least one third insulating member comprises an insulating ceramic material, quartz, or a metal oxide.

18. The plasma processing apparatus according to claim 11, wherein
the first insulating member includes:
a first insulating portion between the upper electrode and the chamber, and
a second insulating portion located outward from the first insulating portion, on the shield, and between the chamber and the shield.

19. The plasma processing apparatus according to claim 18, further comprising:
at least one other insulating member located below the shield and between the chamber and the shield, the shield being supported between the second insulating portion of the first insulating member and the at least one other insulating member.

20. A plasma processing apparatus, including:
a chamber defining a plasma processing space;
a substrate support in the chamber, the substrate support being configured to support a substrate;
an upper electrode located above the substrate support, the upper electrode being a part of a ceiling extending above the plasma processing space and closing an opening of the chamber, the upper electrode being configured to receive radio-frequency power;
a first insulating member being a part of the ceiling, the first insulating member being located between the upper electrode and the chamber to electrically isolate the upper electrode from the chamber; and
a shield being another part of the ceiling, the shield being conductive and comprising a silicon-containing material, the shield extending from a peripheral edge of the upper electrode to the chamber and the shield extending from a peripheral edge of the first insulating member to the chamber;
at least one second insulating member located outward from the first insulating member, on the shield, and between the chamber and the shield,
wherein the upper electrode includes:
a ceiling plate facing the plasma processing space and being conductive; and
a first support supporting the ceiling plate and defining at least one gas-diffusion compartment, and
the ceiling includes a portion exposed to the plasma processing space, and the portion includes a conductor including the upper electrode and the shield.
